(19) United States
(12) Patent Application Publication
(10) Pub. No.: US 2021/0316713 A1
(43) Pub. Date: Oct. 14, 2021

(54) SYSTEM AND METHOD FOR RUNTIME PLANNING OF AN ELECTRIC BATTERY POWERED WORK VEHICLE

(71) Applicant: Deere & Company, Moline, IL (US)

(72) Inventors: Eric Vilar, Dubuque, IA (US); Benjamin R. Wagner, Dubuque, IA (US)

(21) Appl. No.: 16/844,241

(22) Filed: Apr. 9, 2020

(51) Int. Cl. B60W 20/10; B60L 50/61; B60L 58/12; B60L 1/00; B60W 10/26; G01R 31/36

(52) U.S. Cl. CPC B60W 20/10; B60L 50/61; B60L 58/12; B60L 1/20; B60W 10/26; B60L 2250/16; B60Y 2200/41; B60L 2200/40; B60L 2240/64; B60W 2510/244; B60W 2710/24; G01R 31/36

(57) ABSTRACT

Systems and methods are disclosed herein for automatically planning the workday of a battery unit powered electric work vehicle. The vehicle includes a chassis supported by traveling devices, itself further supporting a work implement. A battery unit discharges energy for at least assisting with actuation of the traveling devices and/or work implement. A controller receives input data from a user regarding specified missions to be performed by the work vehicle in a given period of time, and predicts rates of energy consumption for at least one operating mode corresponding to each remaining mission to be performed. The controller further generates, to a user interface, output data corresponding to a required charge state of the battery unit based on the predicted rates of energy consumption, relative to a detected current charge state of the battery unit. The controller may monitor activity and/or consumption rates throughout the day and proactively generate outputs for, e.g., usage optimization.

### FIELD OF THE DISCLOSURE

The present disclosure relates generally to battery powered work vehicles in, e.g., the construction and/or agricultural industries which include one or more cooling system fans. More particularly, the present disclosure relates to computer-implemented systems and methods for runtime planning of such work vehicles, based for example on a schedule of desired missions and available battery unit charge.

### BACKGROUND

Battery powered work vehicles as discussed herein may for illustrative purposes be referred to as electric backhoes, but such characterization is non-limiting in scope and unless otherwise specifically noted herein alternative work vehicles may for example include excavator machines, compact wheel or track loaders, grading machines, dump trucks, and the like. These machines may have tracked or wheeled traveling devices supporting the undercarriage from the ground surface, and may further include one or more working implements which are used to modify the working environment (e.g., digging, lifting, loading, grading) in coordination with movement of the machine.

There is an ongoing need in the field of such working machines to reduce diesel emissions, while still providing requisite performance. In some jurisdictions, diesel emissions are to be eliminated in passenger vehicles altogether, which may further prompt the desire for all-electric or hybrid diesel-electric work vehicles. The potential benefits of all-electric work vehicles include not only the reduction in emissions of nitrogen oxides and particulates, but also reductions in service times and of noise in the work environment, not to mention fuel savings.

However, existing battery units (typically using lithium-ion batteries) have a relatively low performance ceiling with respect to the energy demands of heavy work vehicles. Most batteries can only sustain operation for a subset of the required workday, and access to power sources for recharging of the batteries can be difficult. Even if a charging source can be made available at a work site, the relatively lengthy charging time required for batteries can be highly undesirable if it mandates downtime during what otherwise would be part of the workday.

### BRIEF SUMMARY OF THE DISCLOSURE

The current disclosure provides an enhancement to conventional systems and methods, at least in part by enabling planning and optimization of a workday of a battery powered electric work vehicle. Such systems and methods may preferably enable the implementation of all-electric work vehicles throughout a full eight hour work day, including transportation to one or more work sites, job completion at those work sites, and further transportation of the work vehicle to a preferred destination such as a charging location.

In an embodiment, a self-propelled work vehicle as disclosed herein comprises a chassis supported by a plurality of traveling devices, the chassis further supporting one or more work implements. A battery unit is configured to discharge energy for at least assisting with actuation of one or more of the traveling devices and the work implements. A controller is communicatively linked to the battery unit and a user interface associated with an operator of the work vehicle, and configured to perform a method as follows. The controller receives input data regarding one or more specified missions to be performed by the work vehicle in a given period of time, predicts rates of energy consumption for at least one operating mode corresponding to each remaining mission of the one or more specified missions to be performed, and generates to the user interface output data corresponding to a required charge state of the battery unit based on the predicted rates of energy consumption, relative to a detected current charge state of the battery unit.

In alternative embodiments, the above-referenced method may be performed partially or wholly through interaction with remote or otherwise alternative computing units, aside from the recited controller.

In one exemplary aspect of the above-referenced embodiments, the rates of energy consumption may be predicted based on stored historical information regarding an average energy consumption for the at least one operating mode, and an input amount of time for each associated mission.

The controller may further be configured to correct the predicted rates of energy consumption based on determined work vehicle usage data and associated battery unit discharge data during the given period of time.

The controller may still further be configured to aggregate the determined work vehicle usage data and the associated battery unit discharge data with the historical data for further prediction of energy consumption rates in subsequent periods of time.

In another exemplary aspect of the above-referenced embodiments, the at least one operating mode corresponding to each remaining mission of the one or more missions to be performed may comprise at least one of a travel mode, a work mode, and an idle mode. The controller is communicatively linked to a global positioning system transceiver on the work vehicle. If at least one travel mode is required based on the specified missions to be performed, the controller may be further configured to obtain geolocation data for the work vehicle and determine a travel time from a current location of the work vehicle to respective locations of one or more other missions to be performed in a work mode, and from at least one of said respective locations to a destination charging location.

In another exemplary aspect of the above-referenced embodiments, the predicted rates of consumption may be dependent on input data comprising mission conditions and/or characteristic values correlating with the mission conditions for one or more of the specified missions.

The mission conditions and/or characteristic values correlating with the mission conditions may for example comprise one or more of: a relative load impact for a type of mission; a relative environmental impact for a specified mission; and a relative load impact for a specified terrain of the mission.

In another exemplary aspect of the above-referenced embodiments, the generated output data corresponds to a first display state wherein a required charge state of the battery unit to complete each of the remaining specified missions is less than a detected current charge state of the battery unit.

The generated output data in accordance with such an aspect may further correspond to a second display state wherein a required charge state of the battery unit to complete each of the remaining specified missions is greater than a detected current charge state of the battery unit.

In another exemplary aspect of the above-referenced embodiments, the controller may be configured to ascertain and display a sequence of the one or more specified missions, optimized with respect to at least one specified mission, having an aggregate predicted rate of energy consumption less than a detected current charge state of the battery unit.

In another exemplary aspect of the above-referenced embodiments, the controller may be configured to ascertain and display a subset of the one or more specified missions, optimized with respect to at least one specified mission, having an aggregate predicted rate of energy consumption less than a detected current charge state of the battery unit.

In another exemplary aspect of the above-referenced embodiments, a user interface may enable an associated user to input mission data and corresponding destination data for a plurality of work vehicles, wherein a workday is automatically planned for each of the plurality of work vehicles which completes each specified mission.

The planned workdays may for example be optimized to provide a largest margin of safety with respect to the charge states of each work vehicle, and/or to consider relative capabilities of the work vehicles with respect to particular ones of the specified missions.

A user interface may further enable an associated user to specify parameters comprising a particular one of the work vehicles with respect to a particular one of the missions and/or a specified time in the given period of time, wherein an optimized arrangement and/or sequence of missions is recalculated for each of the plurality of work vehicles which fits the specified parameters.

### BRIEF DESCRIPTION OF THE DRAWINGS

Numerous objects, features and advantages of the embodiments set forth herein will be readily apparent to those skilled in the art upon reading of the following disclosure when taken in conjunction with the accompanying drawings.

FIG. 1 is a side elevation view of a wheeled backhoe excavator as a battery powered work vehicle incorporating an embodiment of a system and method as disclosed herein.

FIG. 2 is a block diagram representing an exemplary control system for the work vehicle of FIG. 1.

FIG. 3 is a flowchart representing an exemplary embodiment of a method as disclosed herein.

### DETAILED DESCRIPTION

As previously noted, systems and methods as disclosed herein enable planning and workday optimization of a battery powered work vehicle. Accordingly, for a work vehicle powered by a battery unit having a specified maximum charge, the systems and methods as disclosed herein may preferably assist in optimizing mission performance and vehicle usage, and further provide real-time notifications to users such as the machine operators regarding the actual and predicted charge status of the battery unit.

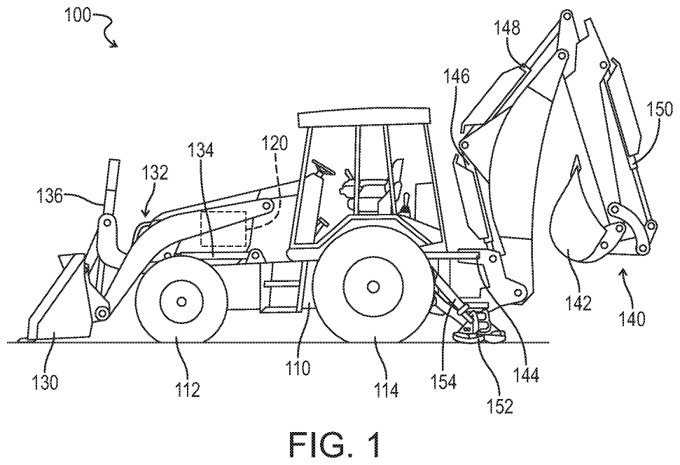

Referring now to the drawings and particularly to FIG. 1, a representative work vehicle is shown and generally designated by the number 100. In the particular example given, and for illustrative purposes throughout the detailed description herein, FIG. 1 shows a loader backhoe 100. The systems disclosed herein may be applicable to similar or otherwise equivalent agricultural, construction, or other vehicles, including for example excavator machines, loaders, graders, and other working machines of the type typically having one or more working implements for modifying the proximate terrain. In certain embodiments, systems and methods as disclosed herein may also be applicable to vehicles lacking explicit work implements.

Work vehicles 100 as discussed herein may typically have tracked or wheeled traveling devices supporting the undercarriage from the ground surface. The backhoe in FIG. 1 is illustrated with front wheels 112 and rear wheels 114 as the traveling devices. The traveling devices may be implemented within the scope of the present disclosure in alternative embodiments as, e.g., belts, steel tracks, or the like. In one example of use, an energy storage device 120 selectively discharges direct-current (DC) electrical energy to one or more power electronic inverters (not shown) which invert the discharged DC energy into alternating-current (AC) energy. The AC energy may be provided to an AC electric motor (not shown) which drives the traveling devices via a transmission for causing the vehicle to self-propel across a surface of the ground.

The energy storage device 120 may generally be described herein as a battery unit 120 including one or more batteries. However, the term “battery unit” as disclosed herein may encompass various forms of energy storage including for example supercapacitors, electrolytic capacitors, hybrid capacitors, and the like, which may have varying charge and discharge cycles but are otherwise capable of storing sufficient energy for operating the work vehicle 100 in various operating modes for a period of time. The battery unit may be configured to operate with a current charge of anywhere between 0% and 100% of a maximum charge, which preferably may be sufficient to complete at least an eight-hour workday. In various embodiments as disclosed herein the energy storage device may be the primary power source for driving the traveling devices 112, 114, but in alternative embodiments a hybrid configuration may be within the scope of the present disclosure where the energy storage device is used in selective conjunction with an engine-driven AC generator, i.e., to at least assist in operations such as actuation of the traveling devices, work implements, and/or other vehicle components.

The work vehicle 100 includes an operator cab supported by a chassis 110 to house and protect the operator of vehicle. The operator cab and the one or more working implements 130, 142 may be mounted on the main frame so that the operator cab faces in the working direction of the working implements. The operator cab may take numerous conventional forms, including for example one or more user interface devices (not shown) such as a display unit, foot pedals, a steering wheel, joysticks, buttons, and any other controls or indicators necessary to operate the vehicle.

As previously noted, the work vehicle 100 may include one or more work implements, which in the illustrated embodiment of FIG. 1 are a front-mounted bucket 130 (i.e., a loader) and a rear-mounted bucket 142 (i.e., a backhoe). In alternative embodiments the work implements may include only one of the aforementioned implements, or, e.g., shovels, blades, tillers, mowers, and the like. Buckets 130, 142 are moveably coupled to the chassis 110 for working the terrain, e.g., scooping, carrying, and dumping dirt and other materials. The front-mounted bucket 130 may be moveably coupled to a front end of the chassis 110 via a first boom assembly 132, including a plurality of hydraulic actuators for moving the front-mounted bucket relative to the chassis. The first boom assembly may include hydraulic lift cylinders 134 for raising and lowering the first boom assembly and a hydraulic tilt cylinder 136 for tilting (e.g. digging and dumping) the front-mounted bucket. The rear-mounted bucket 142 may be moveably coupled to a rear end of the chassis via a second boom assembly 140, including a plurality of hydraulic actuators for moving the rear-mounted bucket relative to the chassis. The second boom assembly may include, e.g., a plurality of hydraulic swing cylinders 144 for swinging the second boom assembly from side to side, a hydraulic lift cylinder 146 for raising and lowering the second boom assembly, a hydraulic crowd cylinder 148 for bending the second boom assembly, and a hydraulic tilt cylinder 150 for tilting (e.g. digging and dumping) the rear-mounted bucket. The operator may selectively control movement of the buckets 130, 142 using controls located within the operator cab, such as one or more of the above-referenced user interface devices.

The exemplary work vehicle 100 as shown in FIG. 1 may still further include right-side and left-side stabilizers 152 for supporting and stabilizing the work vehicle on the ground, especially in modes wherein one or more of the buckets 130, 142 are in operation. Hydraulic lift cylinders 154 may be implemented for raising and lowering the stabilizers 152 relative to the chassis 110 of the work vehicle.

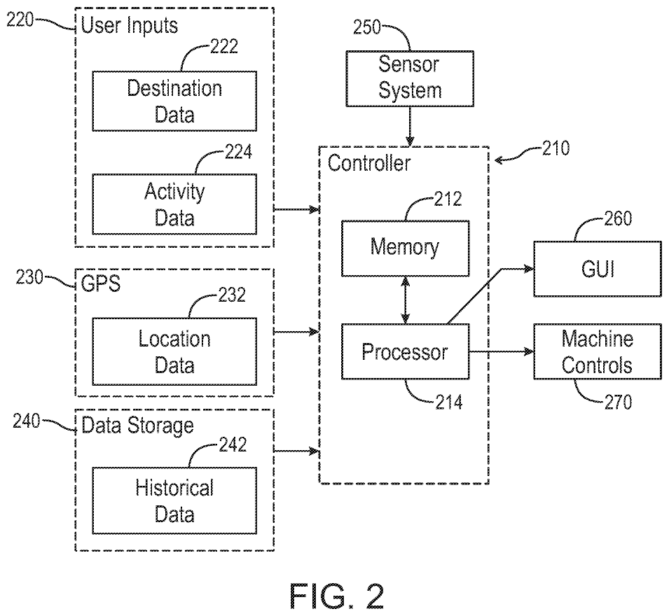

As schematically illustrated in FIG. 2, the work vehicle 100 includes a control system including a controller 210. The controller may be part of a central control system of the work vehicle, or it may be a separate control module. The controller may include one or more user interface devices as referenced above, and may optionally be mounted in the operator cab at a control panel.

The controller 210 is configured to receive input signals from some or all of various sensors collectively defining a sensor system 250. Certain of these sensors may be provided to detect machine operating conditions or positioning, including for example an orientation sensor, global positioning system (GPS) sensors, vehicle speed sensors, vehicle implement positioning sensors, and the like, and whereas one or more of these sensors may be discrete in nature the sensor system may further refer to signals provided from the machine control system. Other sensors in the sensor system 250 may be provided to detect ambient conditions including for example obstacles in the path and/or vicinity of the work vehicle, and may include laser scanners, thermal sensors, imaging devices, structured light sensors, ultrasonic sensors, and other optical sensors. The types and combinations of obstacle sensors may vary for a type of working machine, work area, and/or application, but generally are provided and configured to optimize recognition of obstacles in a working path of the vehicle. More particularly with respect to embodiments of the present disclosure, the sensor system 250 may further include sensors configured to detect a current charge state of the battery unit 120, collectively or for example as individual values for each of a plurality of batteries associated with a battery unit 120.

The controller 210 as shown is further configured to receive input data regarding specified missions to be performed by the work vehicle in a given period of time, for example in the form of user input signals 220 via one or more of the aforementioned user interface devices. As further detailed below, the operator may provide destination data 222 and activity data 224 to the controller as information in the form of alphanumeric text, selectable codes, and the like.

The controller 210 as shown is further configured to receive location data 232 corresponding to, e.g., the current geolocation of the work vehicle 100, one or more destination locations of the work vehicle, including for example at least a final destination with a charging station, and/or route information there between. Such location data may be provided via a global positioning system (GPS) 230, for example provided from sensors located at the destinations, third party sources, and/or from sensors/transceivers located on the work vehicle which may also be characterized as one of the sensors in the sensor system 250.

The controller 210 as shown is further configured to receive historical data 242 from data storage 240. Data storage as discussed herein may, unless otherwise stated, generally encompass hardware such as volatile or non-volatile storage devices, drives, memory, or other storage media, as well as one or more databases residing thereon. The historical data may correspond to one or more specified activities, destinations, locations, and any other metrics or parameters as implemented by the controller for determining or predicting consumption rates in a given work period. The data storage may be external to the controller, and even to the work vehicle itself, wherein the historical data may for example be uploaded to the controller on demand. Alternatively, the data storage may be internal to the controller if the controller is configured accordingly.

The controller 210 may be configured to produce output data within the scope of the present disclosure, as further described below, to a graphical user interface 260 for display to the human operator. Such output data may comprise real-time feedback relating to vehicle operation and/or mission performance, such as for example corresponding to a required charge state of the battery unit based on predicted rates of energy consumption, relative to a detected current charge state of the battery unit. The graphical user interface may in certain embodiments itself be configured to provide the user inputs 220 to the controller. The controller may also be configured to generate control signals 270 for controlling the operation of respective actuators, or signals for indirect control via intermediate control units, associated with a machine steering control system, a machine implement control system, and/or a machine drive control system (not shown).

The controller 210 includes or may be associated with a memory unit 212 and a processor 214, and in certain embodiments may include a communication unit (not shown). It is understood that the controller described herein may be a single controller having all of the described functionality, or it may include multiple controllers wherein the described functionality is distributed among the multiple controllers.

Various operations, steps or algorithms as described in connection with the controller 210 can be embodied directly in hardware, in a computer program product such as a software module executed by the processor 214, or in a combination of the two. The computer program product can reside in the memory unit 212, such as for example RAM memory, flash memory, ROM memory, EPROM memory, EEPROM memory, registers, hard disk, a removable disk, or any other form of computer-readable medium known in the art. An exemplary computer-readable medium can be coupled to the processor such that the processor can read information from, and write information to, the memory/storage medium. In the alternative, the medium can be integral to the processor. The processor and the medium can reside in an application specific integrated circuit (ASIC). The ASIC can reside in a user terminal. In the alternative, the processor and the medium can reside as discrete components in a user terminal.

The term “processor” 214 as used herein may refer to at least general-purpose or specific-purpose processing devices and/or logic as may be understood by one of skill in the art, including but not limited to a microprocessor, a microcontroller, a state machine, and the like. A processor can also be implemented as a combination of computing devices, e.g., a combination of a DSP and a microprocessor, a plurality of microprocessors, one or more microprocessors in conjunction with a DSP core, or any other such configuration.

Although not shown, a communication unit may be provided to support or provide communications between the controller 210 and external systems or devices, and/or support or provide communication interface with respect to internal components of the work vehicle 100. The communications unit may include wireless communication system components (e.g., via cellular modem, WiFi, Bluetooth or the like) and/or may include one or more wired communications terminals such as universal serial bus ports.

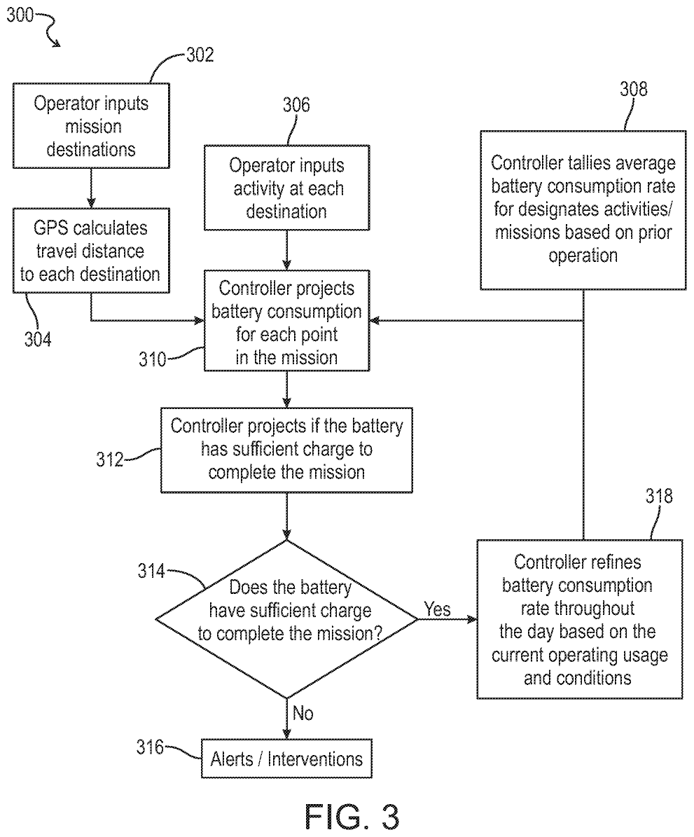

Referring generally to FIG. 3, an exemplary method of operation 300 may further be described for planning a workday of the aforementioned battery powered work vehicle 100. The term “workday” as used herein may preferably constitute at least an eight-hour period of time, but may refer to any specified period of time in which a sequence of one or more missions are to be performed. The term “mission” as used herein may generally connote a required action to be performed and requiring one or more operating modes which may include, without limitation, active modes, idle modes, and traveling operating modes for any one or more combinations of work vehicle components (e.g., work implements, traveling devices, etc.). For example, an exemplary workday may include transporting of the work vehicle on-road to one or more destinations (e.g., work sites), completing specified jobs at those work sites, and then returning to a final destination, which may be the location of origin or a new location, to recharge the battery unit(s). With respect to a particular specified job, the work vehicle (i.e., a battery powered loader backhoe) may for example be expected to operate in some combination of a backhoe mode, a loader mode, and/or an idle mode for portions of the allotted time.

The method 300 as disclosed herein preferably allows an operator (e.g., the operator physically present in the operator cab during operation or a remote user such as an administrator) of the work vehicle to plan a full workday and be confident that the battery unit will not deplete before the work vehicle is transported to its recharging station at the end of the day.

In one initial step 302, the operator is enabled via user interface devices (e.g., the graphical user interface) of the work vehicle to provide input data corresponding to one or more mission destinations. The user interface devices may typically be located in a control panel of the work vehicle, but alternatively the system may incorporate a user interface executable on a computing device associated with the operator, such as for example via a mobile computing application or a hosted web page enabling such inputs with respect to a given work vehicle. As previously noted, the mission destinations may typically include one or more specified work sites and a charging destination. However, charging modes and capabilities may be anticipated at one or more work sites, and in some cases a work site may accordingly constitute an end of the specified workday.

The controller may implement GPS information corresponding to a current location of the work vehicle and to the locations for each of the specified destinations for calculating a travel distance there between (step 304). The controller may further incorporate other data to determine a time of travel or other relevant measurement which corresponds not only to the travel distance but other parameters such as for example the means of travel, road quality, and/or other ambient conditions. In one exemplary alternative, the travel distances and/or times involved may be provided directly by the operator in step 302.

In addition to the entry of mission destinations, the operator may further be enabled via the user interface devices of the work vehicle (or via an executable user interface on the operator's computing device) to provide input data corresponding to specifications of required activity at (or prior, between, or after) each previously specified destination (step 306). In some embodiments, the operator may select or enter specific activities associated with a total period of time at a given destination. The operator may further specify an amount of time to be spent in each of a plurality of operating modes corresponding with the specific activities. Alternatively, the operator may select one or more general work codes for the given destination, wherein the system estimates a set of activities that are to be performed, or retrieves historical information associated with the work code(s) and/or the given destination for the purpose of determining or predicting the required activity for a given work period.

Based on the information provided from the operator in steps 302 and 306, further in view of any associated determinations or calculations performed by the system with respect to the required missions, the controller in the present embodiment further tallies an average battery consumption rate for each associated mode of operation, and combines that rate with how long the battery will run in each associated mode of operation (step 308). Consumption rate tallies at the start of each day may be determined from historical data regarding prior usage (e.g., with respect to the specified missions, destinations, work vehicle, etc.). In an embodiment, the controller predicts rates of energy consumption for at least one operating mode corresponding to each specified mission. Rates of energy consumption may for example be predicted based on stored historical information regarding an average energy consumption for the at least one operating mode corresponding to each specified mission, and an input (e.g., user-specified or calculated by the controller) amount of time for each associated mission. As further noted below, subsequent consumption rate tallies performed throughout the workday can be further refined or corrected based on collected or determined data regarding the work vehicle usage and relevant current conditions, such as for example an associated battery unit discharge during the given period of time.

The rates of battery consumption may be characterized specifically for an associated mode of operation, or otherwise may be characterized based on a number of contextual influences. In an embodiment, the predicted rates of consumption are dependent on input data comprising mission conditions and/or characteristic values correlating with the mission conditions for one or more of the specified missions. The mission conditions and/or characteristic values correlating with the mission conditions may include a relative load impact for a type of mission, a relative environmental impact for a specified mission, and/or a relative load impact for a specified location of the mission. For example, the controller may be configured to account for one or more influences comprising “most likely” rates of consumption, “severe” duty rates of consumption, “climate dependent” rates of consumption, “terrain dependent” rates of consumption, or the like, as may be predetermined for retrieval and processing by the controller or as may be developed over time using machine learning algorithms, or a combination thereof.

Upon receiving or determining the information from the preceding steps, the controller further predicts how much battery charge will need to be consumed to complete the specified missions, i.e., road trips and jobs at each work site (step 310). As previously noted, the controller receives real-time sensor output information regarding the current charge state of the battery unit, wherein the controller may further project whether the current charge state of the battery unit is sufficient to complete the specified missions in the workday (step 312). At any given time after combining the tallies and time at-load, continuously or upon demand throughout the workday, the controller may be configured to provide feedback to the operator for how much battery charge is needed to complete the planned workday. Such real-time feedback may merely compare the battery charge state remaining to the amount of charge needed to complete each of the remaining missions, or the feedback may be further broken down with respect to the amount of charge needed to complete individual ones of the remaining missions.

If the current charge state of the battery unit(s) is not sufficient to complete one or more of the specified missions in the workday (i.e., “no” in response to the query in step 314), the controller may be configured to provide feedback to the operator in the form of an alert (step 316), which may be visual and/or audible in nature. The feedback may be provided via output data generated to a display unit within a field of view of the operator during normal operation to indicate visually the current charge state of the battery unit, wherein the output feedback corresponds to a first display state (e.g., normal, or OK) when a required charge state of the battery unit to complete each of the remaining specified missions is less than a detected current charge state of the battery unit, and the output corresponds to a second display state (e.g., an alert) when a required charge state of the battery unit to complete each of the remaining specified missions is greater than a detected current charge state of the battery unit. In one example, the controller may cause the display unit to indicate visually the current charge state of the battery unit, further highlighted using color changes, blinking lights, etc. Alternatively, indicator lights and/or buzzers which correspond to an insufficient charge state may be implemented.

In an embodiment, the controller may respond to an insufficient charge of the battery unit by performing one or more interventions. For example, the controller may disable one or more components or actions of the work vehicle, pending further manual input from the operator. Alternatively, the controller may implement or recommend a different sequence of missions in the workday, or modifications to one or more of the specified missions. The controller may be configured to make such recommendations for optimization of the workday, based for example on a priority assigned to each of the missions manually by the operator or based on historical data. The controller may be configured to enact interventions for optimization of one or more specified missions, for example to reduce the amount of battery consumption during missions. The controller may be configured to provide real time feedback regarding whether the battery unit even has enough charge to return to its home or to reach its next recharge station, and further to recommend an alternative destination for charging.

If the current charge state of the battery unit(s) is determined to be sufficient to complete all of the specified missions in the workday (i.e., “yes” in response to the query in step 314), the controller may be configured to continue with the specified activities but further refine the initial determinations regarding battery consumption rates, based for example on information collected throughout the day with respect to current operating usage and conditions (step 318), and further return to step 310 for projections of battery consumption with respect to the remaining missions in the workday. As previously noted, the controller may rely on user inputs and/or historical data in making the initial predictions of a necessary battery charge for completion of the specified missions in a workday. These inputs may be constantly or periodically tested against the actual usage during the workday to determine any changes in the actual battery consumption, or otherwise stated to provide updated predictions with respect to the necessary battery charge for completion of the specified missions. This step may be facilitated in various embodiments by aggregating the work vehicle usage data and associated battery unit discharge data previously collected during the workday with the previously stored historical data for further prediction of energy consumption rates in subsequent periods of time, such as for example subsequent workdays but also including the remaining missions (if any) in the current workday.

In an embodiment, the controller may further recommend modifications to the current workday plan (i.e., sequence of specified missions) in view of the updated predictions with respect to the necessary battery charge for completion of the specified missions.

The embodiment of the illustrated method 300 in FIG. 3 enables an operator to provide a specified list of missions and a sequence thereof, wherein the controller projects a necessary charge of the battery unit to complete the associated workday. In one exemplary embodiment, the controller only intervenes with the operator selections when the necessary charge state for completion of the workday is less than (or within a threshold margin of safety with respect to) the actual charge state of the battery unit. In an alternative embodiment of the method, the system may enable operator specification of individual missions and associated destinations, either by desired chronological order or by priority, and further optimize the initial sequence of missions at the beginning of the workday. Such optimization may be programmatic for reducing the risk of premature discharge, based for example on the potential for heightened workload and battery consumption for certain missions, or to ensure that the work vehicle is proximate to a reliable charging station throughout periods of the workday when the vehicle is at heightened risk of reaching a low charge state, etc.

Responsive to user input prioritizing at least one specified mission, the controller may be configured to ascertain and display a sequence of the one or more specified missions for the workday, optimized with respect to the at least one prioritized mission, having an aggregate predicted rate of energy consumption less than a detected current charge state of the battery unit. Alternatively, the controller may be configured to ascertain and display a subset of the one or more specified missions for the workday, optimized with respect to the at least one prioritized mission, having an aggregate predicted rate of energy consumption less than a detected current charge state of the battery unit.

The controller may still further or alternatively be configured to optimize a sequence of operating modes associated with a specified mission at a work site, for the purpose of minimizing battery consumption in completing the mission. In a variant thereof, the controller may be configured to optimize operating parameters for the work vehicle, such as for example by setting maximums to one or more operating parameters or by determining and applying a functional relationship between a variable which is characteristic of the specified mission (e.g., corresponding to work site conditions, load severity, or the like) and of one or more operating parameters of the work vehicle. In either of these embodiments, the controller may automatically implement changes in the operating parameters of the work vehicle for optimization purposes, or the controller may generate recommended settings for operator confirmation or implementation thereof.

In an embodiment, a system as disclosed herein may enable an administrator to input mission data and corresponding destination data for a plurality of work vehicles, wherein the system is configured to automatically plan a workday for each of the plurality of work vehicles which completes each of the specified missions. The system may optimize the planned workdays to provide a largest margin of safety with respect to the charge states of each vehicle, or the optimization may further or alternatively consider relative capabilities of the work vehicles with respect to particular ones of the specified missions. The system may provide a user interface which enables the user to specify a particular one of the work vehicles with respect to a particular one of the missions, even for example at a specified time in the workday, wherein the system further recalculates an optimized arrangement and/or sequence of missions for each of the plurality of work vehicles which fits the parameters given by the user. Accordingly, it may be possible to mutually coordinate the deployment of multiple work vehicles and thereby maximize the amount of missions performed and/or minimize the impact of projected battery consumption.

In an embodiment, systems and methods as disclosed herein may be implemented for hybrid work vehicles which are capable of operating in a fully electric (battery powered) capacity or in a partially electric capacity which selectively uses diesel engine power. In such embodiments, the controller may for example be configured to optimize a sequence of missions in a workday to minimize the amount of diesel engine power required to complete a workday, or to ensure that diesel engine power is not required at all for specific missions during the workday, or the like.

Thus, it is seen that the apparatus and methods of the present disclosure readily achieve the ends and advantages mentioned as well as those inherent therein. While certain preferred embodiments of the disclosure have been illustrated and described for present purposes, numerous changes in the arrangement and construction of parts and steps may be made by those skilled in the art, which changes are encompassed within the scope and spirit of the present disclosure as defined by the appended claims. Each disclosed feature or embodiment may be combined with any of the other disclosed features or embodiments.

What is claimed is:

1. A self-propelled work vehicle comprising:
a chassis supported by a plurality of traveling devices, the chassis further supporting one or more work implements;
a battery unit configured to discharge energy for at least assisting with actuation of one or more of the traveling devices and the work implements; and
a controller communicatively linked to the battery unit and a user interface associated with an operator of the work vehicle, the controller configured to
receive input data regarding one or more specified missions to be performed by the work vehicle in a given period of time,
predict rates of energy consumption for at least one operating mode corresponding to each remaining mission of the one or more specified missions to be performed, and
generate output data to the user interface, the output data corresponding to a required charge state of the battery unit based on the predicted rates of energy consumption, relative to a detected current charge state of the battery unit.

2. The self-propelled work vehicle of claim 1, wherein:
the rates of energy consumption are predicted based on stored historical information regarding an average energy consumption for the at least one operating mode, and an input amount of time for each associated mission.

3. The self-propelled work vehicle of claim 2, wherein:
the controller is further configured to correct the predicted rates of energy consumption based on determined work vehicle usage data and associated battery unit discharge data during the given period of time.

4. The self-propelled work vehicle of claim 3, wherein:
the controller is further configured to aggregate the determined work vehicle usage data and the associated battery unit discharge data with the historical data for further prediction of energy consumption rates in subsequent periods of time.

5. The self-propelled work vehicle of claim 1, wherein:
the at least one operating mode corresponding to each remaining mission of the one or more missions to be performed comprise at least one of a travel mode, a work mode, and an idle mode,
the controller is communicatively linked to a global positioning system transceiver on the work vehicle, wherein if at least one travel mode is required based on the specified missions to be performed, the controller is configured to obtain geolocation data for the work vehicle and determine a travel time from a current location of the work vehicle to respective locations of one or more other missions to be performed in a work mode, and from at least one of said respective locations to a destination charging location.

6. The self-propelled work vehicle of claim 1, wherein:
the predicted rates of consumption are dependent on input data comprising mission conditions and/or characteristic values correlating with the mission conditions for one or more of the specified missions.

7. The self-propelled work vehicle of claim 6, wherein the mission conditions and/or characteristic values correlating with the mission conditions comprise one or more of:
a relative load impact for a type of mission;
a relative environmental impact for a specified mission; and
a relative load impact for a specified terrain of the mission.

8. The self-propelled work vehicle of claim 1, wherein:
the generated output data corresponds to a first display state wherein a required charge state of the battery unit to complete each of the remaining specified missions is less than a detected current charge state of the battery unit, and
the generated output data corresponds to a second display state wherein a required charge state of the battery unit to complete each of the remaining specified missions is greater than a detected current charge state of the battery unit.

9. The self-propelled work vehicle of claim 1, wherein:
the controller is configured to ascertain and display a sequence of the one or more specified missions, optimized with respect to at least one specified mission, having an aggregate predicted rate of energy consumption less than a detected current charge state of the battery unit.

10. The self-propelled work vehicle of claim 1, wherein:
the controller is configured to ascertain and display a subset of the one or more specified missions, optimized with respect to at least one specified mission, having an aggregate predicted rate of energy consumption less than a detected current charge state of the battery unit.

11. A method of planning a work period for a self-propelled work vehicle, the work vehicle comprising a chassis supported by a plurality of traveling devices, the chassis further supporting one or more work implements, and a battery unit configured to discharge energy for at least assisting with actuation of one or more of the traveling devices and the work implements, the method comprising:
obtaining input data regarding one or more specified missions to be performed by the work vehicle in a given period of time;
predicting rates of energy consumption for at least one operating mode corresponding to each remaining mission of the one or more specified missions to be performed; and
generating output data to a user interface associated with the work vehicle, the output data corresponding to a required charge state of the battery unit based on the predicted rates of energy consumption, relative to a detected current charge state of the battery unit.

12. The method of claim 11, wherein:
the rates of energy consumption are predicted based on stored historical information regarding an average energy consumption for the at least one operating mode, and an input amount of time for each associated mission.

13. The method of claim 12, further comprising
correcting the predicted rates of energy consumption based on determined work vehicle usage data and associated battery unit discharge data during the given period of time.

14. The method of claim 13, further comprising:
aggregating the determined work vehicle usage data and the associated battery unit discharge data with the historical data for further prediction of energy consumption rates in subsequent periods of time.

15. The method of claim 11, wherein the at least one operating mode corresponding to each remaining mission of the one or more missions to be performed comprise at least one of a travel mode, a work mode, and an idle mode, the method further comprising:
if at least one travel mode is required based on the specified missions to be performed, obtaining geolocation data for the work vehicle and determining a travel time from a current location of the work vehicle to respective locations of one or more other missions to be performed in a work mode, and from at least one of said respective locations to a destination charging location.

16. The method of claim 11, wherein:
the predicted rates of consumption are dependent on input data comprising mission conditions and/or characteristic values correlating with the mission conditions for one or more of the specified missions.

17. The method of claim 16, wherein the mission conditions and/or characteristic values correlating with the mission conditions comprise one or more of:
a relative load impact for a type of mission;
a relative environmental impact for a specified mission; and
a relative load impact for a specified terrain of the mission.

18. The method of claim 11, wherein:
the generated output data corresponds to a first display state wherein a required charge state of the battery unit to complete each of the remaining specified missions is less than a detected current charge state of the battery unit, and
the generated output data corresponds to a second display state wherein a required charge state of the battery unit to complete each of the remaining specified missions is greater than a detected current charge state of the battery unit.

19. The method of claim 11, further comprising:
ascertaining and displaying a sequence of the one or more specified missions, optimized with respect to at least one specified mission, having an aggregate predicted rate of energy consumption less than a detected current charge state of the battery unit.

20. The method of claim 11, further comprising:
ascertaining and displaying a subset of the one or more specified missions, optimized with respect to at least one specified mission, having an aggregate predicted rate of energy consumption less than a detected current charge state of the battery unit.
